(19) United States
(12) Patent Application Publication
(10) Pub. No.: US 2012/0181509 A1
(43) Pub. Date: Jul. 19, 2012

(54) GRAPHENE DEVICE AND METHOD FOR MANUFACTURING THE SAME

(76) Inventors: Qingqing Liang, Beijing (CN); Zhi Jin, Beijing (CN); Wenwu Wang, Beijing (CN); Huicai Zhong, Beijing (CN); Huilong Zhu, New York, NY (US)

(21) Appl. No.: 13/143,932

(22) PCT Filed: Feb. 23, 2011
(86) PCT No.: PCT/CN11/71194

§ 371 Date: Jul. 10, 2011

(30) Foreign Application Priority Data
Oct. 29, 2010 (CN) 201010532003.1

(51) Int. Cl. H01L 29/775; H01L 21/335

(52) U.S. Cl. 257/29; 438/301; 257/E29.245; 257/E21.404

(57) ABSTRACT

A graphene device structure and a method for manufacturing the same are provided. The graphene device structure comprises: a graphene layer; a gate region formed on the graphene layer; and a doped semiconductor region formed at one side of the gate region and connected with the graphene layer, wherein the doped semiconductor region is a drain region of the graphene device structure, and the graphene layer formed at one side of the gate region is a source region of the graphene device structure. The on/off ratio of the graphene device structure may be improved by the doped semiconductor region without increasing the band gaps of the graphene material, so that the applicability of the graphene material in CMOS devices may be enhanced without decreasing the carrier mobility of graphene materials and speed of the devices.

### CROSS REFERENCE TO RELATED APPLICATIONS

The present application is a Section 371 National Stage Application of International Application No. PCT/CN2011/071194, filed on Feb. 23, 2011, which claims the benefit of Chinese Patent Application No. 201010532003.1, filed on Oct. 29, 2010. The entire disclosures of both applications are incorporated herein by reference.

### BACKGROUND OF THE INVENTION

1. Field of the Invention

The present invention generally relates to a semiconductor device and a method for manufacturing the device, and more particularly, to a graphene device and a method for manufacturing the same.

2. Description of Prior Art

At present, the international prospective advanced research is mainly focused on whether CMOS devices can be formed based on silicon semiconductor substrates as before after the 11 nm-16 nm technical node. One of the most popular research topics is to develop materials having higher carrier mobility and new techniques to further extend Moore's Law and beyond Si-CMOS, so as to advance development of integrated circuits (ICs).

Graphene materials receive extensive attention because of their excellent physical properties such as high carrier mobility, high conductive capability, high thermal conductivity, etc., and are widely considered as a prospective carbon based material. Although the graphene material represents many outstanding physical properties, there still exist challenges for its application in CMOS device as a channel material having high carrier mobility because of its band gap of nearly zero. Present researches indicate that the on/off ratio of a graphene device can be improved by increasing the band gap of the graphene device at the cost of more or less degradation of carrier mobility or speed of the graphene device.

Therefore, it is necessary to provide a graphene device structure and a method for manufacturing the device in which the on/off ratio of a graphene device may be improved without increasing the band gap of the graphene material so as not to degrade the speed of the device.

### SUMMARY OF THE INVENTION

In order to solve the problems described above, the present invention provides a graphene device structure that comprises: a graphene layer; a gate region formed on the graphene layer; and a doped semiconductor region formed at one side of the gate region and connected with the graphene layer, wherein the doped semiconductor region is a drain region of the graphene device structure, and the graphene layer formed at one side of the gate region is a source region of the graphene device structure.

In addition, the present invention further provides a method for manufacturing the graphene device structure, comprising: A: providing a substrate which comprises an insulating layer and a semiconductor layer formed thereon; B: forming a doped semiconductor region and an isolating layer that are in contact with each other in the semiconductor layer; C: forming a graphene layer on the isolating layer and on a portion of the doped semiconductor region, and forming a gate region on the graphene layer along the direction in which the doped semiconductor region and the isolating layer are in contact with each other, wherein the doped semiconductor region is a drain region of the graphene device structure, and the graphene layer formed at one side of the gate region is a source region of the graphene device structure.

In the device structure of the present invention, the doped semiconductor region in contact with the graphene layer can be formed on one side of the gate region. The on/off ratio of the graphene device can be improved by the doped semiconductor region without increasing the band gaps of graphene material, such that carrier mobility of the graphene material (i.e., speed of the device) may not be decreased, and the applicability of the graphene material in the CMOS device may be enhanced.

### BRIEF DESCRIPTION OF THE DRAWINGS

FIG. 1 shows a schematic view of a graphene device structure according to an embodiment of the present invention;

FIG. 2 shows an energy band diagram of an n-type graphene device structure in each operating mode according to an embodiment of the present invention;

FIG. 3 shows an energy band diagram of a p-type graphene device structure in each operating mode according to an embodiment of the present invention; and

FIGS. 4-8A show schematic views in each step of manufacturing a graphene device structure according to an embodiment of the present invention.

### DETAILED DESCRIPTION OF THE EMBODIMENTS

The present invention provides a graphene device structure and a method for manufacturing the same. Hereafter, the present invention will be described in detail with reference to embodiments in conjunction with the accompanying drawings. Many different embodiments and examples are provided to implement different structures of the present invention as disclosed below. Components and arrangements of given examples are described only as examples to simplify disclosure of the present invention in the following in order not to limit the invention. In addition, some reference numbers and/or characters can be repeated in different examples of the present invention for simplification and clearness without indication of the relationship in examples and arrangement of different embodiments that are discussed. Although examples of various specific processes and/or materials are provided in the embodiments of the present invention, a person of ordinary skill in the art may recognize applicability of other techniques and/or other materials. In addition, the structure in which a first feature is located on the second feature may comprise an embodiment in which the feature is in direct contact with the second feature and an embodiment in which another feature is formed between the first and the second features such that the first character is not in direct contact with the second feature.

FIG. 1 shows a schematic view of a graphene device structure according to an embodiment of the present invention. The graphene device structure comprises: a graphene layer 202 which may comprise one or more layers of graphene atoms; a gate region 204 in contact with the graphene layer 202, wherein the gate region 204 comprises a gate dielectric layer 204-1 and a gate electrode 204-2, the gate dielectric layer 204-1 comprises SiO₂, SiON or high-K dielectric materials (having higher dielectric constant compared with SiO₂) such as HfO₂, HfSiO, HfSiON, HfTaO, HfTiO, HfZrO, Al₂O₃, La₂O₃, ZrO₂, LaAlO, or any combination thereof and/or other suitable materials, and the gate electrode 204-2 comprises polysilicon or metals (for example, TIN); a doped semiconductor region 206 formed at one side of the gate region and in contact with the graphene layer 202, wherein the doped semiconductor region 206 is made of semiconductor materials and is heavily n-type or p-type doped, the doped semiconductor region 206 is isolated from the gate region 204, the doped semiconductor region 206 is the drain region of the graphene device structure, and the graphene layer 202 formed at the other side of the gate region is the source region of the graphene device structure. The on/off ratio can be improved by the doped semiconductor region 206.

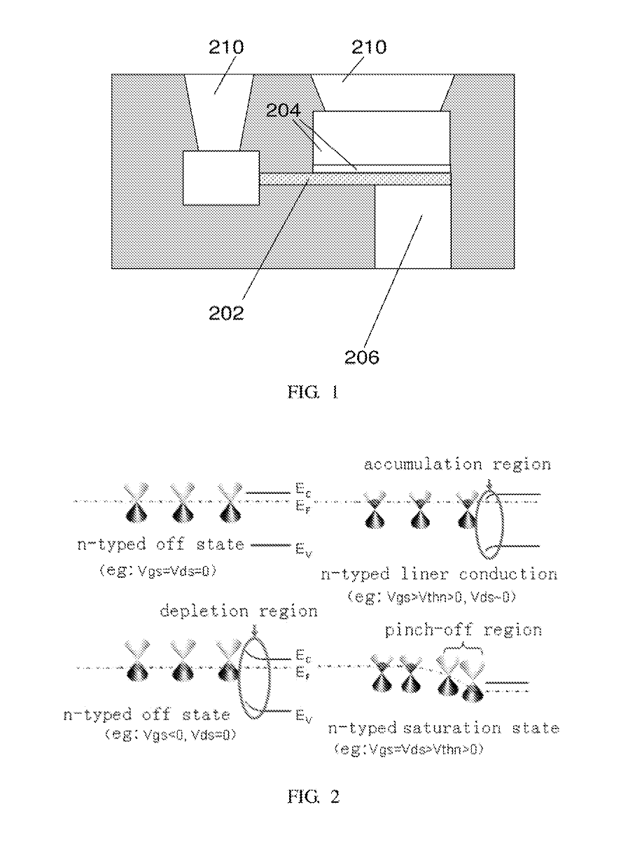

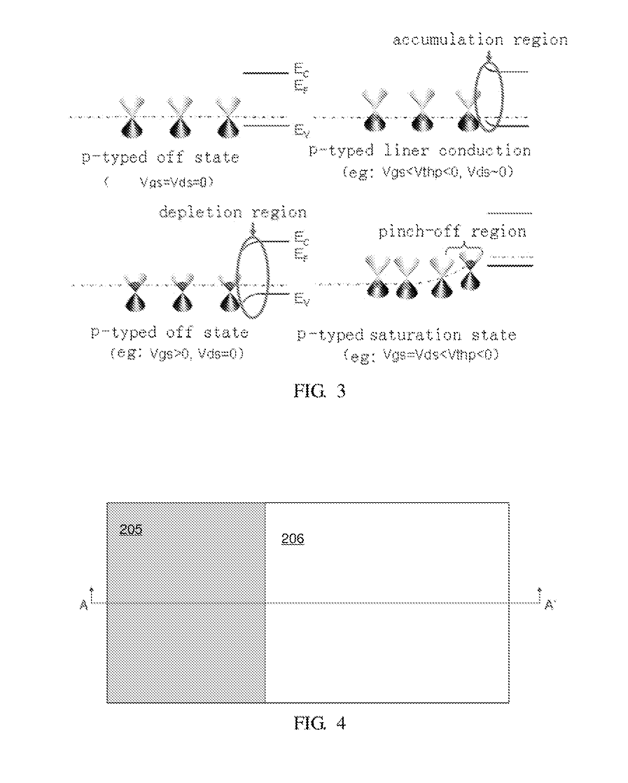

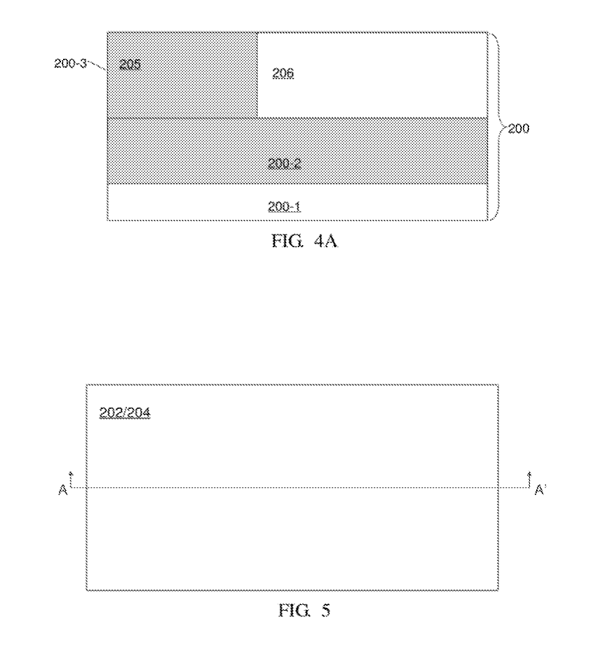

For better understanding of the present invention, energy band diagrams of the n-type and p-type graphene devices will be described in detail with reference to FIG. 2 and FIG. 3, in which the n-type graphene device indicates that the doped semiconductor region is n-type doped, the p-type graphene device indicates that the doped semiconductor region is p-type doped, Vgs denotes a gate-to-source voltage, Vds denotes a drain-to-source voltage, and Vthn and Vthp denote threshold voltages of n-type and p-type devices, respectively.

Referring to FIG. 2 which shows an energy band diagram of an n-type graphene device in each operating mode, when the gate-bias is lower than the threshold voltage (Vgs≦0), the device is in cut-off state in which the fermi energy level is lower than the Dirac point with reference to FIG. 2 illustrating the energy band diagram in the cut-off state, and therefore the carriers are holes. As the doped semiconductor region is n-type doped, the holes in the graphene layer may transit over higher potential barrier in order to travel through the drain region, which may result in switching off of the device. And the leakage current is in inverse proportion to the potential barrier height. When the gate-bias is higher than the threshold voltage (Vgs>0), the ferimi energy level in the graphene layer is higher than the Dirac point, thus the carriers are electrons for which the n-type doped semiconductor region may not form potential barriers, and therefore the device is switched on, as shown in FIG. 2 which shows a energy band diagram in a linear conductive state or a saturation state. Also, because there is no limit to band gaps of the graphene in the device, high mobility can be achieved.

Referring to FIG. 3 which shows an energy band diagram of an n-type graphene device in each operating mode, when the gate-bias is higher than the threshold voltage (Vgs≧0), the device is in the cut-off state, as shown in the energy band diagrams in FIG. 3. In such a case the fermi energy level is higher than the Dirac point, and therefore the carriers are electrons. Because the semiconductor region is p-type doped, the electrons in the graphene may transit over a higher potential barrier in order to travel through the source region, such that the device is switched off and the leakage current is in inverse proportion to the barrier height. When the gate-bias is lower than the threshold voltage (Vgs<0), the ferimi energy level in the graphene is lower than the Dirac point, thus the carriers are holes for which the n-type doped semiconductor region may not form potential barriers, and therefore the device is switched on, as shown in FIG. 3 which shows the energy band diagram in a linear conductive or saturated state. Also, because there is no limit to band gaps of the graphene in the device, high mobility can be achieved.

The graphene device and the energy band diagram in the present invention are described in detail as above. In the graphene device structure of the present invention, the on/off ratio of the graphene device can be improved by the n-type or p-type doped semiconductor region without decreasing the carrier mobility of the graphene material and speed of the semiconductor device, and therefore the applicability of the graphene material in the CMOS device may be enhanced.

An embodiment of the method for manufacturing the graphene device structure will be described in detail hereinafter with reference to FIGS. 4-8A which show schematic views for intermediate steps of the embodiment of the method for manufacturing the graphene device comprising top views and section views in AA′ direction.

In step S01, a substrate is provided which comprises an insulating layer and a semiconductor layer formed thereon. The substrate may be an SOI substrate 200 that comprises a top silicon 200-3 which is the semiconductor layer of the substrate, a buried oxide layer 200-2 which is the insulating layer of the substrate, and a back substrate 200-1, as illustrated in FIG. 4A.

In step S02, an isolating layer and a doped semiconductor region that are in contact with each other are formed in the semiconductor layer 200-3 of the substrate, as illustrated in FIG. 4 (top view) and FIG. 4A (section view in AA direction).

In the embodiments of the present invention, after etching the top silicon 200-3 to form grooves, dielectric materials comprising silicon nitride, silicon dioxide or other insulating materials are deposited and planarized to form the isolating layer 205. Then the doped semiconductor region 206 is formed in the semiconductor layer which is adjacent to the isolating layer 205 by n-type or p-type heavily doping.

In step S03, a graphene layer is formed on the isolating layer and a part of the doped semiconductor region, and a gate region is formed on the graphene layer along the direction in which the doped semiconductor region and the isolating layer are in contact with each other.

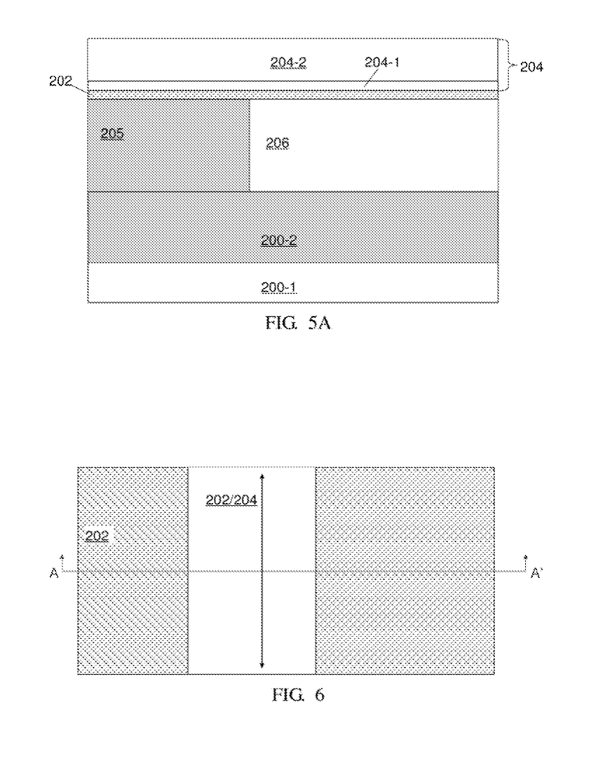

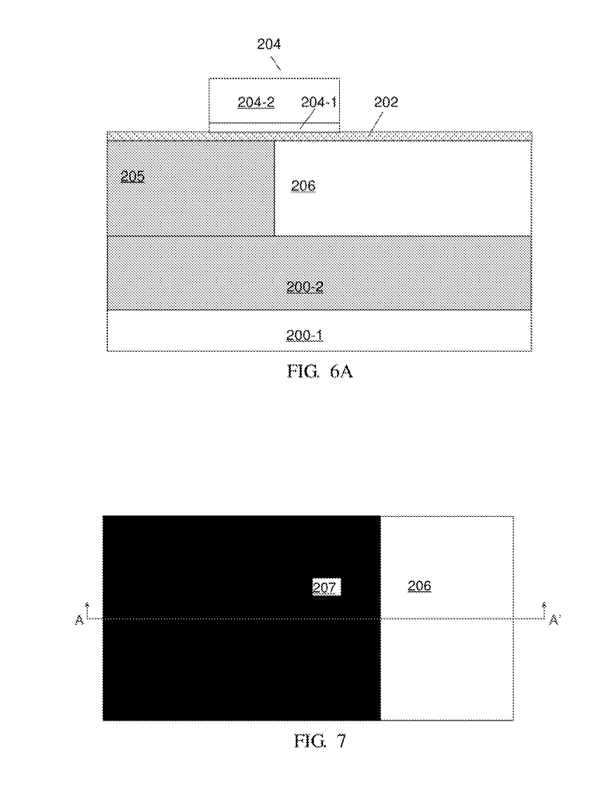

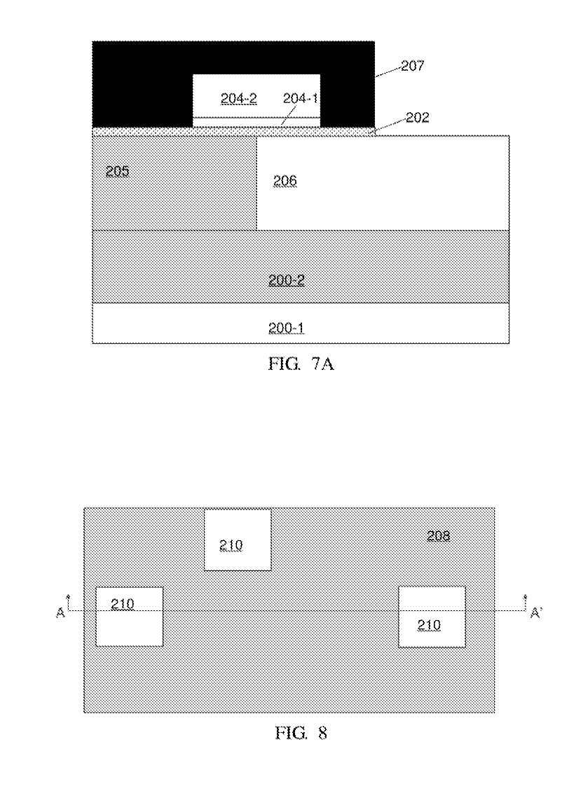

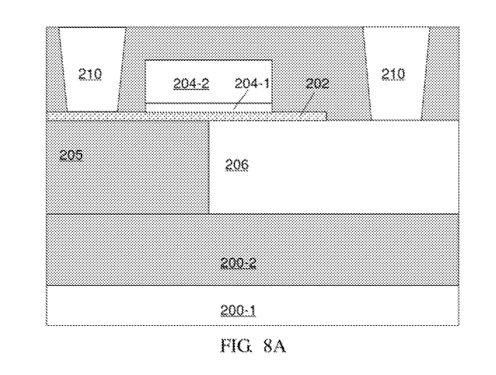

Specifically, referring to FIG. 5 and FIG. 5A (section view in AA′ direction), a graphene layer 202, a gate dielectric layer 204-1 and a gate electrode 204-2 are formed sequentially. One or more layers of graphene materials may be formed by CVD, thermal decomposition, micromechanical peeling-off, bonding for transferring, or other methods as appropriate. The gate dielectric layer 204-1 may comprise SiO₂, SiON or high-K dielectric materials (having higher dielectric constant compared with SiO₂) such as HfO₂, HfSiO, HfSiON, HfTaO, HfTiO, HfZrO, Al₂O₃, La₂O₃, ZrO₂, LaAlO, or any combination thereof and/or other suitable materials. The gate electrode 204-2 may be formed of polysilicon or metals (for example, TIN), and may be formed by sputtering, CVD, PLD, MOCVD, ALD, PEALD or other suitable methods. Then, the gate dielectric layer 204-1 and the gate electrode 204-2 are patterned, as illustrated in FIG. 6 and FIG. 6A (section view in AA′ direction), to form the gate region 204 along the direction (indicated by the arrow in FIG. 7) in which the doped semiconductor region 206 and the isolating layer 205 are in contact with each other. Next, a masking layer 207 such as photo-sensitive etchant is formed to cover the gate region 204 and a portion of the graphene layer on the semiconductor-doped region 206, and the uncovered graphene layer is etched off to expose a portion of the doped semiconductor region 206, as illustrated in FIG. 7 and FIG. 7A (section view in AA′ direction), and then the masking layer 207 is removed. In the present embodiment, the doped semiconductor region 206 is the drain region of the graphene device structure, and the graphene layer 202 formed at one side of the gate region 204 on the isolating layer 205 is the source region of the graphene device structure. The on/off ratio can be improved by the doped semiconductor region 206. Further, an inter-layer dielectric layer 208 may be formed on the device by depositing dielectric materials such as SiO₂ and then planarizing the same by the Chemical Mechanical Polishing (CMP) method. Then the inter-layer dielectric layer 208 is etched to form contact holes. The contact holes are filled with metals such as W, Cu and so on to form contacts 210, such that contacts are formed on the source/drain regions and on the gate region, as illustrated in FIG. 8 and FIG. 8A (section view in AA′ direction).

Although the present invention has been disclosed in detail as above with reference to preferred embodiments, the method for manufacturing the device is only illustrative. It is apparent for the person of ordinary skill in the art that the graphene device may be formed by other methods. Therefore, the present invention should not be limited to the embodiments disclosed herein.

The embodiment of the graphene device and the method for manufacturing the device are described in detail as above. The band gap in the graphene may be increased by forming the n-type or p-type doped semiconductor region in contact with the graphene layer without degrading the carrier mobility of the graphene, and the on/off ratio of the graphene device may be improved without decreasing the speed of the device, such that the applicability of the graphene material in CMOS devices may be enhanced.

Although the present invention has been disclosed as above with reference to preferred embodiments thereof, the present invention will not be limited thereto. Those skilled in the art can modify and vary the embodiments without departing from the spirit and scope of the present invention. Accordingly, the scope of the present invention shall be defined in the appended claims.

In addition, the application scope of the present invention shall not be limited to the technique, mechanism, fabrication, composition, means, methods and steps of the particular embodiment described above. From the contents disclosed in the present invention, a person of ordinary skill in the art may recognize application of the techniques, mechanism, fabrication, composition, means, methods and steps being existed or to be developed in future, which may implement substantially the same function as the corresponding embodiments described in the present invention or achieve substantially the same results. Accordingly, it is intended that all such techniques, mechanism, fabrication, composition, means, methods and steps shall fall within the scope of the present invention defined in the appended claims.

What is claimed is:

1. A graphene device structure, comprising:
a graphene layer;
a gate region formed on the graphene layer; and
a doped semiconductor region formed on one side of the gate region and in contact with the graphene layer,
wherein the doped semiconductor region is the drain region of the graphene device structure, and the graphene layer formed on the other side of the gate region is the source region of the graphene device structure.

2. The graphene device structure according to claim 1, wherein the doped semiconductor region is formed under the graphene layer at the one side of the gate region.

3. The graphene device structure according to claim 1, wherein the doped semiconductor region is n-type or p-type doped.

4. The graphene device structure according to claim 1, wherein the doped semiconductor region is heavily-doped.

5. The graphene device structure according to claim 1, wherein the gate region comprises a gate dielectric layer and a gate electrode.

6. The graphene device structure according to claim 5, wherein the gate region comprises polysilicon or metals.

7. The graphene device structure according to claim 1, further comprising contacts formed on the source region, on the drain region and on the gate region.

8. A method for manufacturing a graphene device structure, comprising:
A: providing a substrate which comprises an insulating layer and a semiconductor layer formed thereon;
B: forming a doped semiconductor region and an isolating layer in contact with each other in the semiconductor layer; and
C: forming a graphene layer on the isolating layer and on a portion of the doped semiconductor region, and forming a gate region on the graphene layer along the direction in which the doped semiconductor region and the isolating layer are in contact with each other;
wherein the doped semiconductor region is a drain region of the graphene device structure, and the graphene layer formed at one side of the gate region is a source region of the graphene device structure.

9. The method for manufacturing a graphene device structure according to claim 8, wherein the substrate is a SOI substrate which comprises a top silicon, a buried oxide layer and a back substrate.

10. The method for manufacturing a graphene device structure according to claim 9, wherein the step B comprises:
patterning and filling the top silicon to form the isolating layer; and
forming the doped semiconductor region in the top silicon.

11. The method for manufacturing a graphene device structure according to claim 8, wherein the doped semiconductor region is heavily-doped.

12. The method for manufacturing a graphene device structure according to claim 8, wherein the doped semiconductor region is n-type or p-type doped.

13. The method for manufacturing a graphene device structure according to claim 8, wherein the step C comprises:
forming the graphene layer on the graphene device structure;
forming the gate region on the graphene layer along the direction in which the doped semiconductor region and the isolating layer are in contact with each other; and
removing portions of the graphene layer on the doped semiconductor region that is not covered by the gate region.

14. The method for manufacturing a graphene device structure according to claim 8, where the step C further comprises:
forming an inter-layer dielectric layer on the device; and
forming contacts on the gate region, on the drain region and on the source region.
